(19) United States
(12) Patent Application Publication
(10) Pub. No.: US 2010/0310137 A1
(43) Pub. Date: Dec. 9, 2010

(54) IMAGE SENSING DEVICE ADAPTED TO FLAT SURFACE DESIGN

(76) Inventors: Bruce C. S. CHOU, Hsin Chu City (TW); Chen-Chih Fan, Hsin Chu County (TW)

Correspondence Address: Muncy, Geissler, Olds & Lowe, PLLC, 4000 Legato Road, Suite 310, FAIRFAX, VA, 22033, US

(21) Appl. No.: 12/796,169

(22) Filed: Jun. 8, 2010

(30) Foreign Application Priority Data
Jun. 9, 2009 (TW) 098119145

(51) Int. Cl. G06K 9/00; H01L 31/0224; H01L 31/09

(52) U.S. Cl. 382/124; 250/214.1

(57) ABSTRACT

An image sensing device adapted to a flat surface design includes a carrier and an image sensing structure. The carrier has carrier input pads and carrier output pads respectively electrically connected to the carrier input pads. The image sensing structure has signal input pads and signal output pads respectively electrically connected to the signal input pads. The signal output pads are respectively electrically connected to the carrier input pads. The image sensing structure includes a sensing chip having image sensing members and a processing circuit. The signal input pads and the image sensing members are electrically connected to the processing circuit. The image sensing members sense an image of an object and output sensed signals. The processing circuit processes the sensed signals into processed signals, which are transmitted to the carrier output pads through the signal input pads, the signal output pads and the carrier input pads.

This application claims priority of No. 098119145 filed in Taiwan R.O.C. on Jun. 9, 2009 under 35 USC 119, the entire content of which is hereby incorporated by reference.

### BACKGROUND OF THE INVENTION

1. Field of the Invention

The invention relates to an image sensing device, and more particularly to an image sensing device adapted to a flat surface design.

2. Related Art

The conventional image sensing device, such as a fingerprint sensor, is packaged by way of wire bonding with injection molding coverage. Therefore, the exposed surface of the packaged sensing device is not a flat surface. When the sensor is assembled into an electronic apparatus, such as a notebook computer, a personal digital assistant, a mobile telephone or the like, a concave ID design is formed on the electronic apparatus to cause a bad outlook. More specifically, when the fingerprint sensor is a swipe-type fingerprint sensor, users cannot easily touch the sensing surface while swiping their fingers over the dip sensor below the horizontal plane. Thus, a clear fingerprint image cannot be obtained through this dip sensor design.

Thus, it is an important subject of the invention to provide an image sensing device adapted to a flat surface design so that the pretty exterior can be obtained.

### SUMMARY OF THE INVENTION

It is therefore an object of the invention to provide an image sensing device adapted to a flat surface design so that the image sensing device can be conveniently fixed to an electronic apparatus and the electronic apparatus can have the fully flat surface and the good look and can be easily used.

The invention achieves the above-identified object by providing an image sensing device adapted to a flat surface design. The image sensing device includes a carrier and an image sensing structure. The carrier has a plurality of carrier input pads and a plurality of carrier output pads. The carrier input pads are respectively electrically connected to the carrier output pads. The image sensing structure has a plurality of signal input pads and a plurality of signal output pads. The signal input pads are respectively electrically connected to the signal output pads. The signal output pads are respectively electrically connected to the carrier input pads. The image sensing structure includes a sensing chip having a plurality of image sensing members and a processing circuit. The signal input pads and the image sensing members are electrically connected to the processing circuit. The image sensing members sense an image of an object and output a plurality of sensed signals. The processing circuit processes the sensed signals into a plurality of processed signals. The processed signals are transmitted to the carrier output pads through the signal input pads, the signal output pads and the carrier input pads.

The image sensing device may further include a baseplate, which is disposed under the carrier and has a plurality of baseplate input pads respectively electrically connected to the carrier output pads.

Thus, the overall image sensing device may be regarded as a packaged product having the thickness greater than 1 mm, so that the product can be conveniently and firmly mounted on the electronic apparatus with the flat casing.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic illustration showing an image sensing device according to a first embodiment of the invention.

FIG. 2 is a schematic illustration showing an image sensing device according to a second embodiment of the invention.

FIG. 3 is a schematic illustration showing an image sensing device according to a third embodiment of the invention.

FIG. 4 is a schematic illustration showing the image sensing device of the invention mounted on a casing of an electronic apparatus.

### DETAILED DESCRIPTION OF THE INVENTION

The present invention will be apparent from the following detailed description, which proceeds with reference to the accompanying drawings, wherein the same references relate to the same elements.

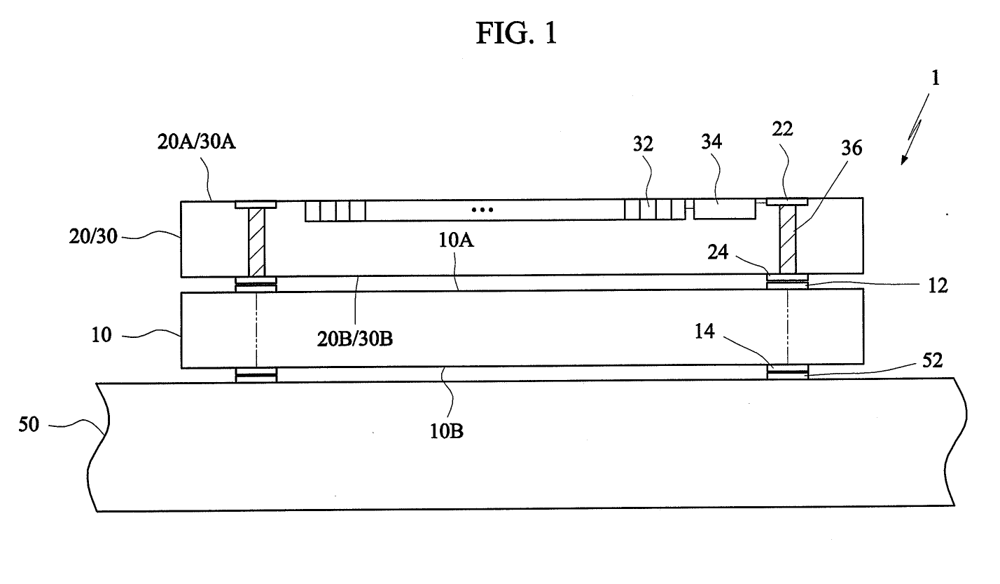

FIG. 1 is a schematic illustration showing an image sensing device 1 according to a first embodiment of the invention. Referring to FIG. 1, the image sensing device 1 of this embodiment is adapted to a flat surface design and includes a carrier 10 and an image sensing structure 20. The image sensing device 1 may be a fingerprint sensor, a finger vein sensor or any other biometrics sensor. The fingerprint sensor may be a swipe-type fingerprint sensor for sensing the surface texture of an object (e.g., the fingerprint or vein pattern of the finger) swiping thereover.

The carrier 10 has a front side 10A and a backside 10B. The carrier 10 has a plurality of carrier input pads 12 disposed on the front side 10A, and a plurality of carrier output pads 14 disposed on the backside 10B. The carrier input pads 12 are respectively electrically connected to the carrier output pads 14. In this invention, the carrier 10 is a printed circuit board (PCB) having multiple metal layers, and may be an interposer formed by another substrate.

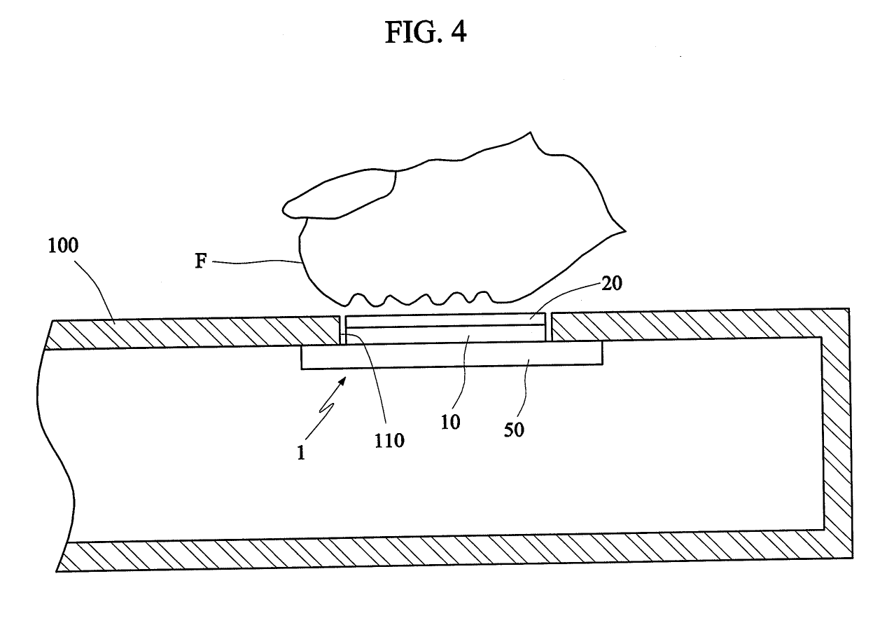

The image sensing structure 20 has a plurality of signal input pads 22 and a plurality of signal output pads 24. The signal input pads 22 are respectively electrically connected to the signal output pads 24. The signal output pads 24 are respectively electrically connected to the carrier input pads 12. The image sensing structure 20 includes a sensing chip 30 having a plurality of image sensing members 32 and a processing circuit 34. The signal input pads 22 and the image sensing members 32 are electrically connected to the processing circuit 34. The image sensing members 32 sense an image of a finger F (see FIG. 4) and output a plurality of sensed signals. The processing circuit 34 processes the sensed signals into a plurality of processed signals. The processed signals are transmitted to the carrier output pads 14 through the signal input pads 22, the signal output pads 24 and the carrier input pads 12.

In addition, the image sensing device 1 may further include a baseplate 50, which is disposed under the carrier 10 and has a plurality of baseplate input pads 52 respectively electrically connected to the carrier output pads 14.

In this embodiment, the signal input pads 22 are electrically connected to the signal output pads 24 respectively through a plurality of vertical conductive plugs 36, and the vertical conductive plugs 36 feed through from an upper surface 20A to a lower surface 20B of the image sensing structure 20. That is, the vertical conductive plugs 36 feed through from an upper surface 30A to a lower surface 30B of the sensing chip 30. In this embodiment, the sensing chip is made of a semiconductor material, especially the silicon (Si) material.

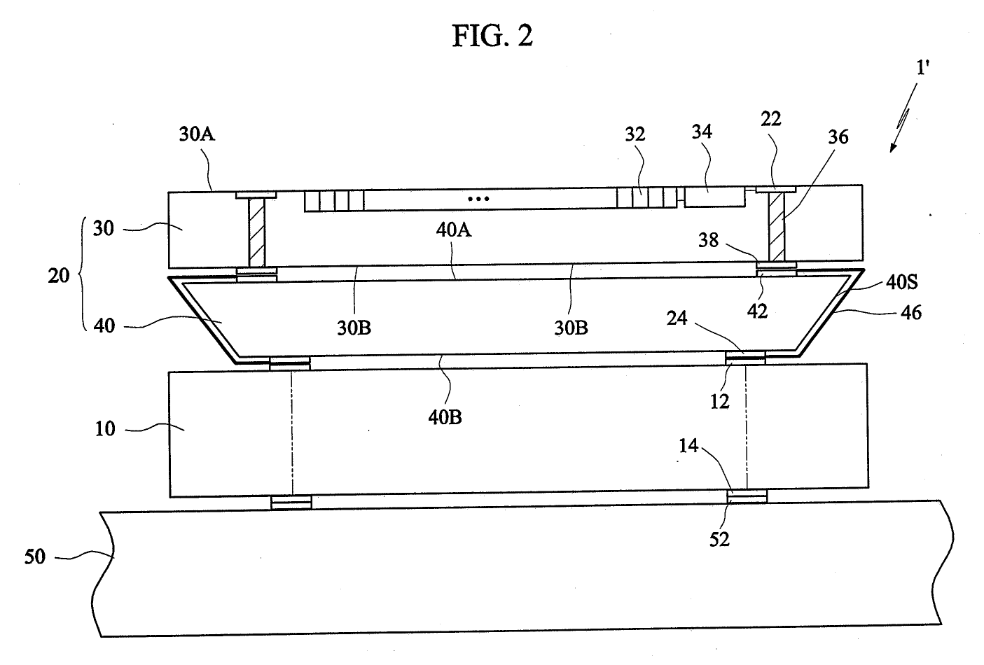

FIG. 2 is a schematic illustration showing an image sensing device 1′ according to a second embodiment of the invention. As shown in FIG. 2, this embodiment is similar to the first embodiment except that the image sensing structure 20 further includes a middle plate 40 disposed between the sensing chip 30 and the carrier 10. The material of the middle plate 40 may be a semiconductor or insulative material. In this embodiment, the material is the glass.

In this embodiment, the signal input pads 22 are electrically connected to the signal output pads 24 respectively through a plurality of vertical conductive plugs 36, a plurality of chip bonding pads 38, a plurality of middle bonding pads 42 and a plurality of interconnect wires 46, and the vertical conductive plugs 36 feed through from the upper surface 30A to the lower surface 30B of the sensing chip 30. The interconnect wires 46 are disposed between the sensing chip 30 and the middle plate 40, and extend to a lower surface 40B of the middle plate 40 along a sidewall surface 40S of the middle plate 40. In this embodiment, the interconnect wires 46 are partially disposed on an upper surface 40A of the middle plate 40, and the sidewall surface 40S is, without limitation to, an inclined surface. The carrier 10, the chip 30 and the middle plate 40 substantially have the same area. The area is perpendicular to the area of a plane along the stacking direction of the carrier 10 and the image sensing structure 20.

In another example, the chip bonding pads 38 and the middle bonding pads 42 may be omitted. In this case, upper portions (horizontal portion) of the interconnect wires 46 between the chip 30 and the middle plate 40 are formed on the backside 30B of the chip 30 by way of coating and selectively etching, and are electrically connected to the vertical conductive plugs 36. Therefore, the signal input pads 22 are electrically connected to the signal output pads 24 respectively through the vertical conductive plugs 36 and the plurality of interconnect wires 46, while the vertical conductive plugs 36 feed through from the upper surface 30A to the lower surface 30B of the chip 30.

In another embodiment, the chip bonding pad 38 and the middle bonding pad 42 may be integrated together during the bonding process. Also, the chip bonding pad 38 and the middle bonding pad 42 may be integrated with the corresponding vertical conductive plug 36 or interconnect wire 46. Thus, the signal input pads 22 may be electrically connected to the signal output pads 24 respectively through the vertical conductive plugs 36 and the interconnect wires 46.

In addition, the image sensing device 1′ of the second embodiment may also further include a baseplate 50, which is disposed under the carrier 10 and has a plurality of baseplate input pads 52 respectively electrically connected to the carrier output pads 14.

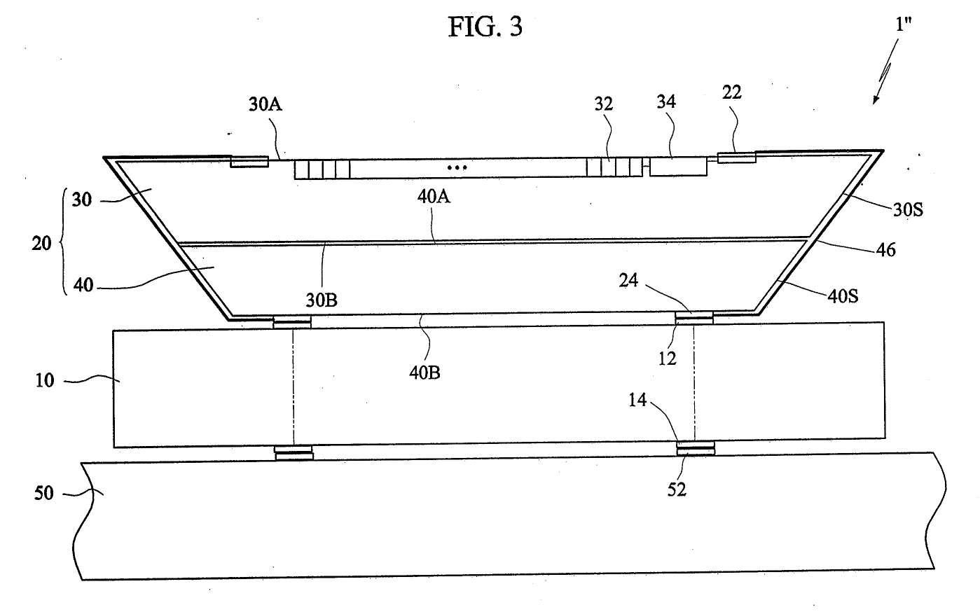

FIG. 3 is a schematic illustration showing an image sensing device 1″ according to a third embodiment of the invention. As shown in FIG. 3, this embodiment is similar to the second embodiment except that the signal input pads 22 are electrically connected to the signal output pads 24 respectively through a plurality of interconnect wires 46. The interconnect wires 46 extend to a lower surface 40B of the middle plate 40 from the upper surface 30A of the chip 30 along a sidewall surface 30S of the chip 30 and a sidewall surface 40S of the middle plate 40. Thus, the sidewall surface 40S of the middle plate 40 and the sidewall surface 30S of the chip 30 are, without limitation to, inclined surfaces and may be arranged on the same plane. In addition, the carrier 10, the chip 30 and the middle plate 40 have substantially the same area. Similarly, the image sensing device 1″ may further include a baseplate 50, which is disposed under the carrier 10 and has a plurality of baseplate input pads 52 respectively electrically connected to the carrier output pads 14.

FIG. 4 is a schematic illustration showing the image sensing device 1 of the invention mounted on a casing 100 of an electronic apparatus. As shown in FIG. 4, the total thickness of the carrier 10 and the image sensing structure 20 may be substantially equal to the thickness of the casing 100. The areas of the carrier 10 and the image sensing structure 20 are substantially equal to the area of an opening 110 of the casing 100. Consequently, the baseplate 50 may be in surface contact with the inner surface of the casing 100, and thus may be firmly fixed to the casing 100 so that the casing 100 and the exposed surface of the image sensing device 1 contacting with the finger F have a fully flat plane structure.

Thus, the overall image sensing device may be regarded as a packaged product having the thickness greater than 1 mm, so that the product can be conveniently and firmly mounted on the electronic apparatus with the flat casing. Consequently, the user can swipe his/her finger over the image sensing device smoothly, and the overall electronic apparatus may have the pretty outlook with this flat surface design.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. An image sensing device adapted to a flat surface design, the image sensing device comprising:
a carrier having a plurality of carrier input pads and a plurality of carrier output pads respectively electrically connected to the carrier input pads; and
an image sensing structure having a plurality of signal input pads and a plurality of signal output pads, wherein the signal input pads are respectively electrically connected to the signal output pads, the signal output pads are respectively electrically connected to the carrier input pads, the image sensing structure comprises a sensing chip having a plurality of image sensing members and a processing circuit, the signal input pads and the image sensing members are electrically connected to the processing circuit, the image sensing members sense an image of an object and output a plurality of sensed signals, the processing circuit processes the sensed signals into a plurality of processed signals, the processed signals are transmitted to the carrier output pads through the signal input pads, the signal output pads and the carrier input pads.

2. The image sensing device according to claim 1, further comprising:
a baseplate, which is disposed under the carrier and has a plurality of baseplate input pads respectively electrically connected to the carrier output pads.

3. The image sensing device according to claim 1, wherein the signal input pads are electrically connected to the signal output pads through a plurality of vertical conductive plugs, respectively, and the vertical conductive plugs feed through from an upper surface to a lower surface of the image sensing structure.

4. The image sensing device according to claim 1, wherein the image sensing structure further comprises a middle plate disposed between the sensing chip and the carrier.

5. The image sensing device according to claim 4, wherein the signal input pads are electrically connected to the signal output pads respectively through a plurality of vertical conductive plugs, a plurality of chip bonding pads, a plurality of middle bonding pads and a plurality of interconnect wires, the vertical conductive plugs feed through from an upper surface to a lower surface of the sensing chip, and the interconnect wires are disposed between the sensing chip and the middle plate, and extend to a lower surface of the middle plate along a sidewall surface of the middle plate.

6. The image sensing device according to claim 4, wherein the signal input pads are electrically connected to the signal output pads respectively through a plurality of vertical conductive plugs and a plurality of interconnect wires, the vertical conductive plugs feed through from an upper surface to a lower surface of the sensing chip, and the interconnect wires are disposed between the sensing chip and the middle plate and extend to a lower surface of the middle plate along a sidewall surface of the middle plate.

7. The image sensing device according to claim 6, wherein the sidewall surface is an inclined surface.

8. The image sensing device according to claim 6, wherein the carrier, the sensing chip and the middle plate have substantially the same area.

9. The image sensing device according to claim 6, further comprising:
a baseplate, which is disposed under the carrier and has a plurality of baseplate input pads respectively electrically connected to the carrier output pads.

10. The image sensing device according to claim 4, wherein the signal input pads are electrically connected to the signal output pads respectively through a plurality of interconnect wires, and the interconnect wires extend to a lower surface of the middle plate from an upper surface of the sensing chip along a sidewall surface of the sensing chip and a sidewall surface of the middle plate.

11. The image sensing device according to claim 10, wherein the sidewall surface of the middle plate and the sidewall surface of the sensing chip are inclined surfaces.

12. The image sensing device according to claim 10, wherein the carrier, the sensing chip and the middle plate have substantially the same area.

13. The image sensing device according to claim 10, further comprising:
a baseplate, which is disposed under the carrier and has a plurality of baseplate input pads respectively electrically connected to the carrier output pads.

14. The image sensing device according to claim 4, wherein a material of the middle plate comprises glass.

15. The image sensing device according to claim 1, wherein the carrier is a printed circuit board having multiple metal layers.

16. The image sensing device according to claim 1, wherein the object is a finger and the image sensing device is a swipe-type fingerprint sensor for sensing a fingerprint of the finger.
